(19) United States
(12) Patent Application Publication
(10) Pub. No.: US 2025/0158573 A1
(43) Pub. Date: May 15, 2025

(54) PSEUDO-DOHERTY LOAD MODULATED BALANCED AMPLIFIER

(71) Applicant: Ampleon Netherlands B.V., Nijmegen (NL)

(72) Inventors: Zhi Geng, Nijmegen (NL); Radjindrepersad Gajadharsing, Nijmegen (NL)

(21) Appl. No.: 18/940,380

(22) Filed: Nov. 7, 2024

(30) Foreign Application Priority Data
Nov. 10, 2023 (NL) 2036239

(51) Int. Cl. H03F 1/02; H03F 1/56; H03F 3/60

(52) U.S. Cl. CPC H03F 1/0288; H03F 1/56; H03F 3/602; H03F 2200/192; H03F 2200/204; H03F 2200/451

(57) ABSTRACT

Example embodiments relate to pseudo-Doherty load modulated balanced amplifiers, PD-LMBAs. One example PD-LMBA is configured to operate in a given frequency band. The PD-LMBA includes a main splitter for splitting an input RF signal into a first signal and a second signal, a main amplifier for amplifying the first signal, a balanced amplifier for amplifying the second signal, and a phase offset unit. The balanced amplifier includes a splitter for splitting the second signal into a first part and a second part of the second signal, a first amplifier and a second amplifier for amplifying the first part of the second signal and the second part of the second signal, respectively, and a combiner. The phase offset unit includes at least one shunt series circuit connected to ground and at least one parallel resonance circuit arranged in between an input and an output of the phase offset unit.

### CROSS-REFERENCE TO RELATED APPLICATIONS

The present application is a non-provisional patent application claiming priority to Netherlands Patent Application No. NL 2036239, filed Nov. 10, 2023, the contents of which are hereby incorporated by reference.

### FIELD OF THE DISCLOSURE

The present application is related to a pseudo-Doherty load modulated balanced amplifier, PD-LMBA and to a mobile telecommunications base station comprising the same. The present application is particularly related to PD-LMBAs that are configured to operate in a given frequency band, wherein a center frequency corresponding to the frequency band lies within a range from 0.5 GHz to 8 GHz, wherein a bandwidth of the frequency band relative to the center frequency lies in a range from 10% to 40%, and/or wherein the PD-LMBA is configured to output a maximum output power in a range from 10 mW to 500 W. These amplifiers can be used for example in industry, cellular, avionics, radar, and medical technologies.

### BACKGROUND

PD-LMBAs are known in the art. A PD-LMBA comprises a main splitter for splitting an input RF signal into a first signal and a second signal. It further comprises a main amplifier for amplifying the first signal, and a balanced amplifier for amplifying the second signal. The balanced amplifier comprises a splitter for splitting the second signal into a first part and a second part of the second signal. The balanced amplifier further comprises a first amplifier and a second amplifier for amplifying the first part of the second signal and the second part of the second signal, respectively. The balanced amplifier further comprises a combiner. This latter combiner is configured for combining the amplified first signal, the amplified first part of the second signal, and the amplified second part of the second signal into an output RF signal.

The first and second amplifiers of the balanced amplifier are typically biased in class C, and the main amplifier in class A/B or class B. For input RF signals having a relatively low power, only the main amplifier will be amplifying signals. For input RF signals having a relatively high power, both the main amplifier and the balanced amplifier will be amplifying signals.

### SUMMARY

Compared to a regular Doherty amplifier, which comprises a main amplifier and a peak amplifier, the PD-LMBA uses a balanced amplifier as peak amplifier. Furthermore, in a PD-LMBA, the output of the main amplifier is connected to a port of the combiner that combines the amplified first and second parts of the second signal with the amplified first signal. This combiner is typically realized using a hybrid coupler of which the isolated port is connected to the output of the main amplifier. Accordingly, there is less or different load modulation of the main amplifier by the balanced amplifier when compared to the load modulation in a regular Doherty amplifier. Hence, the wording pseudo-Doherty amplifier is used to refer to this type of amplifier.

For PD-LMBAs and regular Doherty amplifiers alike, it is important that the various signals are combined in such a way that little to no phase offset exists between the various signals at the point where they are combined. Put differently, at the output of a PD-LMBA, or other location where the various signals are combined and/or co-exist, the phase offset between the amplified first signal and the amplified second signal should be n×360 degrees, with n an integer equal to or larger than 0. To minimize the phase offset, PD-LMBAs and Doherty amplifiers in general comprise phase offset units, such as transmission lines, that can be arranged before and after the various amplifiers.

For example, a regular Doherty amplifier may comprise a splitter that splits an input RF signal into a first part and a second part. The first part is provided to the main amplifier directly, whereas the second part is provided to the peak amplifier via a phase offset unit that provides a phase offset that equals 90 degrees. The amplified first and second parts of the input RF signal are combined at a combining node. The output of the main amplifier is connected to the combining node via an impedance inverter in the form of a quarter wavelength transformer that causes a phase offset of 90 degrees. The output of the peak amplifier is connected to the combining node directly.

In the example above, the phase offset unit arranged upstream of the peak amplifier ensures that the amplified first and second parts of the RF input signal are combined in-phase at the combining node. It should be noted that various other Doherty topologies exist. However, for each topology, similar phase offset units are employed for reducing the phase offset between the amplified first and second parts of the RF input signal when these signals are combined at the combining node. Each phase offset unit causes a phase delay of the signal it operates on.

A zero phase offset can typically not be obtained over the entire frequency band of interest and for all powers of the RF input signal. For example, the electrical length of transmission lines varies with frequency. In addition, the phase offset imparted by the amplifiers differs with input power. Accordingly, both Doherty amplifiers and PD-LMBAs are typically designed to reach a zero phase offset for a given frequency, typically the center frequency, and for a given input power or output power.

Typically, phase offset units are realized using transmission lines. The Applicant has found that for PD-LMBAs, the use of transmission lines is often insufficient to achieve a satisfactory phase offset when viewed within a given a frequency band. This will be explained next.

FIG. 1 illustrates a curve, marked with circles, that describes a desired phase offset to be added to the second signal prior to splitting the second signal into a first and second part such that the signals amplified by the main amplifier and balanced amplifier are combined in-phase. For example, it is desired that the second signal is delayed by 60 degrees when signals of 2 GHz are used.

As can be seen in FIG. 1, the desired phase offset to be added to the second signal is frequency dependent. In the same figure, a curve is shown, marked with crosses, that indicates the phase delay that can be added to the second signal when a transmission line is used.

The phase delay Off_c realized by a transmission line of length l in degrees at the center frequency fc is determined by:

$$Off\_c = 360 \times \frac{l}{λ} = 360 \times \frac{l \cdot fc}{{v}_{ph}}$$

where λ is the wavelength and vₚₕ the phase velocity. The difference Off_h−Off_l in phase delay added to the second signal between two frequencies fh and fl using the same transmission line is given by:

$$Off\_h - Off\_l = 360 \times \frac{l \cdot ( fh - fl )}{{v}_{ph}} = Off\_c \times \frac{fh - fl}{fc}$$

Accordingly, the difference in phase delay, i.e., Off_h−Off_l, that can be achieved over a given frequency band fh−fl using a transmission line is fixed.

In FIG. 1, (fh−fl)/fc=0.2, Off_c=−60, and Offₕ−Offₗ=−12. As can be seen in FIG. 1, the phase delay added by the transmission line to the second signal at low frequencies is too high, whereas the phase delay added by the transmission line to the second signal at high frequencies is too low. Put differently, the derivative of the phase delay added by a transmission line to the second signal with respect to the frequency of that signal is too low.

An object of the present application is to provide a PD-LMBA in which the abovementioned problem is addressed.

According to the present application, this object is achieved using the PD-LMBA as defined in claim 1, which is characterized in that the PD-LMBA further comprises a phase offset unit arranged upstream from the first amplifier and second amplifier and downstream of the main splitter. The phase offset unit comprises at least one shunt series circuit connected to ground, each shunt series circuit comprising an impedance inverter and a termination circuit arranged in between the impedance inverter and ground, wherein the termination circuit is configured to present an RF short to the impedance inverter at a first frequency that lies inside or close to the frequency band. The impedance inverter is configured to transform the RF short to an RF open at the first frequency.

The phase offset unit further comprises at least one parallel resonance circuit arranged in between an input and an output of the phase offset unit, wherein an impedance of the at least one parallel resonance circuit corresponds to an RF open at a second frequency that lies outside the frequency band.

According to some embodiments, the first frequency lies closer to a center frequency of the frequency band than the second frequency does.

Typically, the phase offset unit should provide little to no impedance transformation inside the frequency band while at the same time introduce a phase delay that displays a steeper profile with frequency than a transmission line to at least approximate the desired phase offset behavior. The Applicant has found that these goals can be simultaneously achieved using the phase offset unit as described above.

Within the context of the present disclosure, an impedance should be construed as an RF open when this impedance is large compared to a reference impedance, for example at least 200 percent of the reference impedance or, in some embodiments, 400 percent. Similarly, within the context of the present disclosure, an impedance should be construed as an RF short when this impedance is small compared to the reference impedance, for example at most 25 percent of the reference impedance or, in some embodiments, at most 10 percent. Furthermore, the reference impedance may be an impedance between 25 Ohm and 75 Ohm and, in some embodiments, equal to 50 Ohm.

The impedance inverter of at least one shunt series circuit may comprise a quarter wavelength transmission line or equivalent thereof. In case multiple shunt series circuits are used, each shunt series circuit presents an RF open at its respective first frequency, which first frequency may or may not be identical to the first frequencies of the other shunt series circuit(s). Compared to a parallel resonance circuit that would produce an RF open at the same frequency, the at least one shunt series circuit of the present disclosure allows for an RF open to be realized over a larger bandwidth.

The at least one shunt series circuit may comprise a first shunt series circuit connected between the input of the phase offset unit and ground, and a second shunt series circuit connected between the output of the phase offset unit and ground. In addition, the at least one parallel resonance circuit may comprise a first parallel resonance circuit connected between the input and output of the phase offset unit. In this case, the first frequency of the first shunt series circuit could be different from the first frequency of the second shunt series circuit.

Further to the above, the at least one parallel resonance circuit may comprise a second parallel resonance circuit connected between the first parallel resonance circuit and the output of the phase offset unit. This second parallel resonance circuit and the first parallel resonance circuit are connected at an intermediate node. The at least one shunt series circuit may in this case comprise a third shunt series circuit connected between the intermediate node and ground. In this embodiment, the first frequency of the third shunt series circuit could be different from the first frequency of the first shunt series circuit and different from the first frequency of the second shunt series circuit. Moreover, the second frequency of the first parallel resonance circuit could be different from the second frequency of the second parallel resonance circuit.

The first frequencies of the first, second, and third shunt series circuits could be situated inside the frequency domain and in between the second frequencies of the first and second parallel resonance circuits.

The PD-LMBA may further comprise a printed circuit board or laminate substrate, wherein the main amplifier and balanced amplifier are comprised by one or more semiconductor dies on the printed circuit board or laminate substrate, in a packaged form or as a discrete semiconductor die, wherein the impedance inverter of at least one of said at least one shunt series circuits is embodied as a transmission line on the printed circuit board or laminate substrate. Furthermore, the termination circuit of at least one of said at least one shunt series circuit may comprise a surface mounted device, SMD, capacitor that is connected to ground through a via in the printed circuit board or laminate substrate. Alternatively, or additionally, at least one of said at least one parallel resonance circuit may comprise a transmission line on the printed circuit board or laminate substrate arranged in parallel to an SMD capacitor.

The splitter of the balanced amplifier may comprise a first coupler having a first input port, a second input port, an output port, and an isolated port. The first input port may be connected to an output of the first amplifier, the second input port to an output of the second amplifier, the isolated port to an output of the main amplifier. The output port can be configured to be connected to a load. Furthermore, each of the first input port, second input port, output port, and isolated port has a respective reference impedance Z_{ref}.

The reference impedance for each of the first input port, second input port, output port, and isolated port can be identical.

The first coupler may comprise n stacked discrete couplers, each discrete coupler having a respective port impedance Zᵢ that is identical for all ports and that is higher than Z_{ref}, wherein n is an integer number greater than 1, and wherein i indicates the i-th discrete coupler with i an integer number ranging from 1 to n, and wherein:

$$\frac{1}{{Z}_{ref}} = {\sum }_{i = 1}^{n} \frac{1}{{Z}_{i}}$$

The Applicant has found that by stacking discrete couplers a lower impedance Z_{ref} can be used. This lowers the impedance transformation that needs to be realized between the various amplifier and the first coupler. In an embodiment, each coupler of the stacked discrete couplers is identical. Additionally, or alternatively, Zᵢ=Z_{coupler} for all i. Additionally, or alternatively, Z_{ref} may lie in a range between 5 and 30 Ohm and/or n may equal 2, 3, or 4, and/or Z_{coupler} may equal 50 Ohm.

It should be noted that the abovementioned stacked discrete couplers can be used in PD-LMBAs, such as those defined by the preamble of claim 1, that do not comprise the abovementioned phase offset for lowering the reference impedance Z_{ref} that is associated with each port of the stack of discrete couplers. Additionally, or alternatively, the reference impedance for corresponding ports of the discrete couplers in the stack of couplers may be identical but the reference impedance for different ports of the same coupler may be different.

It is further noted that the present application is also directed to an electronic device that comprises printed circuit board or laminate substrate, and that comprises n stacked discrete couplers as described above.

Corresponding ports of adjacent discrete couplers in the stack of discrete couplers may be electrically connected, for example using solder. Typically, a discrete coupler is provided as an essentially rectangular SMD having electrical terminal at its corners. These terminals extend along the entire edge of the coupler. When the discrete couplers are stacked, these terminals are essentially aligned and can be interconnected using solder.

The PD-LMBA may further comprise a first impedance matching network arranged in between the output of the first amplifier and the first coupler. The first impedance matching network can be configured for providing an upward impedance transformation, in a direction from the first amplifier to the first coupler, to the reference impedance Z_{ref} associated with the first input port of the first coupler. Similarly, the PD-LMBA may comprise a second impedance matching network arranged in between the output of the second amplifier and the first coupler and being configured for providing an upward impedance transformation, in a direction from the second amplifier to the first coupler, to the reference impedance Z_{ref} associated with the second input port of the first coupler. The PD-LMBA may further comprise a third impedance matching network arranged in between the output of the main amplifier and the first coupler and being configured for providing an upward impedance transformation, in a direction from the main amplifier to the first coupler, to the reference impedance Z_{ref} associated with the isolated input port of the first coupler.

The PD-LMBA may further comprise a fourth impedance matching network arranged in between the output port of the first coupler and the output of the PD-LMBA, wherein the fourth impedance matching network is configured for providing an upward impedance transformation between the reference impedance associated with the output port of the first coupler and an impedance of a load to be connected to the output of the PD-LMBA. For example, the load impedance may equal 50 Ohm, whereas the reference impedance associated with the output port of the first coupler may equal 50/2, 50/3, or 50/4 Ohm.

The splitter of the balanced amplifier may comprise a second coupler, wherein the second coupler comprises an input port connected to the main splitter, a first output port connected to an input of the first amplifier, a second output port connected to an input of the second amplifier, and an isolated port connected to a default load. Furthermore, the phase offset unit can be connected between the main splitter and the input port of the second coupler. Alternatively, the phase offset unit may comprise a segment arranged in between the first output port of the second coupler and the input of the first amplifier, and a segment arranged in between the second output port of the second coupler and the input of the second amplifier. The phase delays realized by both segments should be identical. Additionally, or alternatively, the PD-LMBA could further comprise a fourth impedance matching network arranged between the first output port of the second coupler and an input of the first amplifier, and a fifth impedance matching network arranged between the second output port of the second coupler and an input of the second amplifier.

The main splitter may comprise a third coupler, wherein the third coupler comprises an input port connected to an input of the PD-LDMA, a first output port connected to the input port of the second coupler, optionally through the phase offset unit, a second output port connected to an input of the main amplifier, and an isolated port.

The abovementioned first, second, and/or third coupler, may each comprise, and optionally independent from the other, a coupler from the group consisting of hybrid couplers, Lange couplers, directional couplers, coupled-line couplers, strip line couplers, branch line couplers, wave guide couplers, and coax couplers.

The first amplifier, the second amplifier, and the main amplifier may each comprise a power transistor, such as a Silicon based laterally diffused metal oxide semiconductor field-effect transistor, or a Gallium Nitride based field-effect transistor. In example embodiments, the first, second, and third amplifiers are realized using a power transistor of the same type and semiconductor material.

According to a further aspect, the present disclosure provides a mobile telecommunications base station that comprises the PD-LMBA as defined above.

### BRIEF DESCRIPTION OF THE DRAWINGS

Next, example embodiments will be described in more detail referring to the appended drawings.

FIG. 1 illustrates a difference between a desired phase delay as a function of frequency for an example PD-LMBA compared to the phase delay that can be realized using a transmission line.

FIG. 2 illustrates a PD-LMBA, according to example embodiments.

FIG. 3 illustrates a phase offset unit used in the PD-LMBA of FIG. 2, according to example embodiments.

FIGS. 4A-4C illustrate various performance parameters of the PD-LMBA of FIG. 2, according to example embodiments.

FIG. 5 illustrates stacked discrete couplers used in the PD-LMBA of FIG. 2, according to example embodiments.

### DETAILED DESCRIPTION

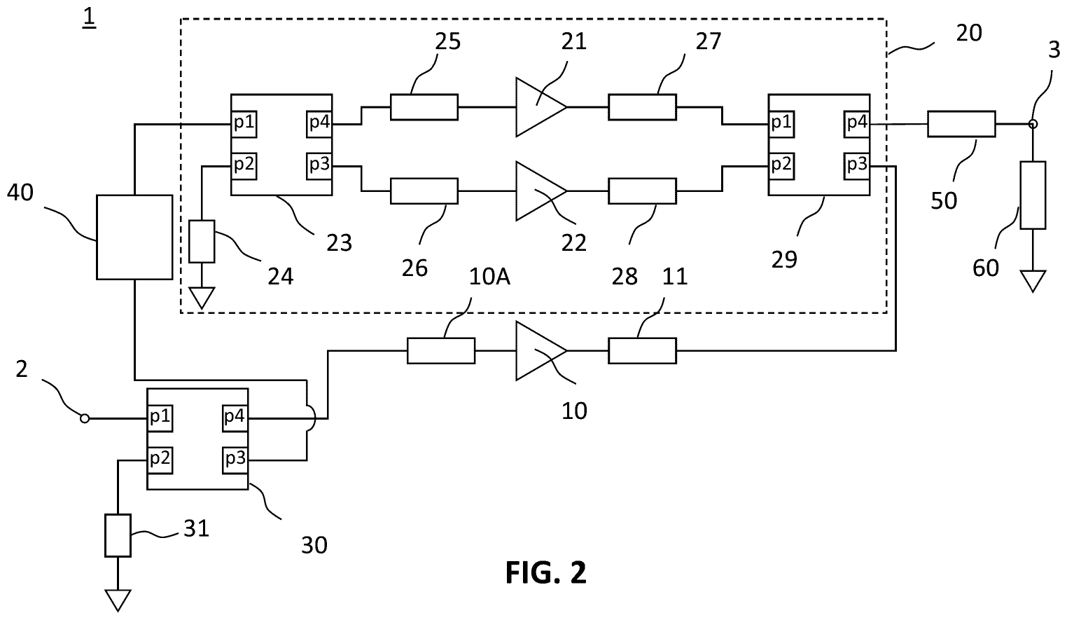

FIG. 2 illustrates an embodiment of a PD-LMBA 1 in accordance with the present disclosure. PD-LMBA 1 comprises a main amplifier 10, and a balanced amplifier 20, wherein balanced amplifier 20 comprises a first amplifier 21 and a second amplifier 22. Main amplifier 10, first amplifier 21, and second amplifier 22, can be identical. However, the present disclosure is not limited thereto and amplifiers 10, 21, 22 can be realized in the same or different semiconductor technologies. Furthermore, the saturated output power of amplifiers 10, 21, 22 may be identical or different depending on the desired back-off behavior of PD-LMBA 1. In the remainder of this document, it will be assumed that amplifiers 10, 21, 22 are identical and are each configured to output the same maximum output power provided that the amplifiers are presented with the same impedance at their outputs. However, main amplifier 10 is balanced in class AB or class B, whereas amplifiers 21, 22 are biased in class C.

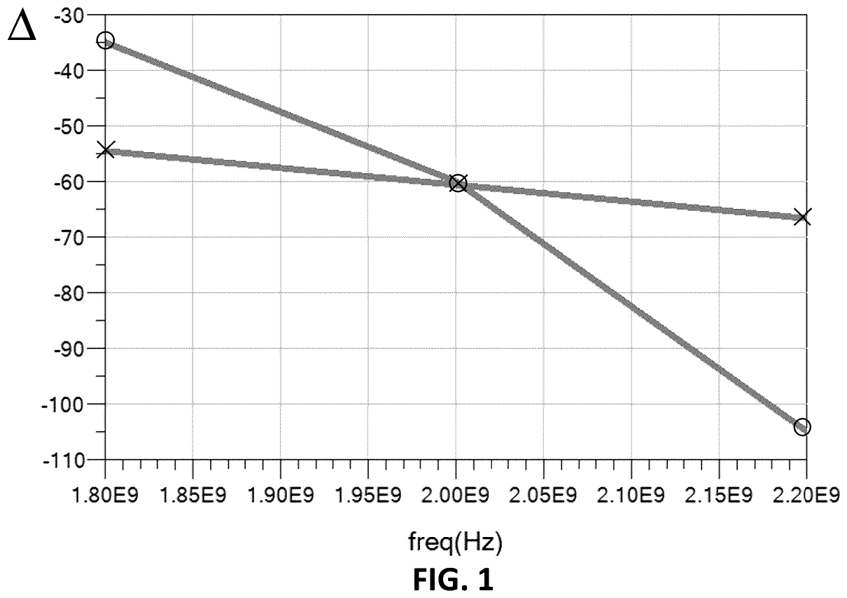

PD-LMBA 1 receives an input RF signal at its input 2. In FIG. 1, input 2 corresponds to or is connected to an input port p1 of a 90 degrees hybrid coupler 30. Hybrid coupler 30, which functions as the main splitter, further comprises a first output port p4, a second output port p3, and an isolated port p2.

A signal received at input port p1, which corresponds to and/or is connected to input 2 of PD-LMBA 1, is distributed over first output port p4 and second output port p3. Moreover, the signal output at second output port p3 has a phase delay of substantially 90 degrees relative to the signal output at first output port p4. Hereinafter, the signal output at first output port p4 will be referred to as the first signal, and the signal output at second output port p3 will be referred to as the second signal.

In FIG. 2, power is not equally distributed over first output p4 and second output port p3. More specifically, the power output to first output port p4 corresponds to −4.77 dB and the power output to second output port p3 corresponds to −1.76 dB. This distribution of power corresponds a ratio of (2/3):(1/3). In addition, isolated port p2 is connected to a termination resistor 31 that has an impedance that corresponds to a reference impedance of hybrid coupler 30, e.g. 50 Ohm.

The second signal is fed to a phase offset unit 40 that imparts a predefined and frequency dependent phase delay to the second signal. The signal from first output port p4 of hybrid coupler 30 is fed to main amplifier 10 via an impedance matching network 10A.

The output of phase offset unit 40 is connected to a splitter in the form of a 90 degrees hybrid coupler 23. Hybrid coupler 23 comprises an input port p1, a first output port p4, a second output port p3, and an isolated port p2. Similar to hybrid coupler 30, isolated port p2 of hybrid coupler 23 is connected to a termination resistor 24 of which an impedance is equal to a reference impedance of hybrid coupler 23, which can be 50 Ohm.

Hybrid coupler 23 splits the second signal received at its input port p1 equally over first output port p4 and second output ports p3. The signal output at first output port p4 is referred to as a first part of the second signal, whereas the signal output at second output port p3 is referred to as a second part of the second signal. Furthermore, the second part of the second signal has a phase delay of substantially 90 degrees relative to the first part of the second signal.

The first part of the second signal is fed to first amplifier 21 through an impedance matching network 25 that matches the reference impedance of first output port p4 of hybrid coupler 23 to an input impedance of first amplifier 21. Similarly, the second part of the second signal is fed to second amplifier 22 through an impedance matching network 26 that matches the reference impedance of second output port p3 of hybrid coupler 23 to an input impedance of second amplifier 22.

First amplifier 21 and second amplifier 22 are connected to respective ports of a combiner 29 that is embodied using a 90 degrees hybrid coupler. More specifically, the output of first amplifier 21 is connected through an impedance matching network 27 to a first input port p1 of hybrid coupler 29, and the output of second amplifier 22 is connected through an impedance matching network 28 to a second input port p2 of hybrid coupler 29. Output port p4 of hybrid coupler 29 is connected through an impedance inverter 50 to a load 60 that is connected to output 3 of PD-LMBA 1. Impedance inverter 50 can be embodied using a quarter wavelength transformer. Isolated port p3 of hybrid coupler 29 is connected through an impedance matching network 11 to an output of main amplifier 10. It should be noted that signals received at first input port p1 of hybrid coupler 29 are coupled to output port p4 of hybrid coupler with a delay of substantially 90 degrees relative to signals received at second input port p2 of hybrid coupler 29.

It should be noted that splitters 23, 30 and combiner 29 may be embodied using a same 90 degrees hybrid coupler. In addition, various types of couplers can be used for realizing splitters 23, 30 and combiner 29. For example, splitters 23, 30 and combiner 29 may each comprise, independently from the other, a coupler out of the group consisting of Lange couplers, directional couplers, coupled-line couplers, strip line couplers, branch line couplers, wave guide couplers, and coax couplers.

Splitters 23, 30 and combiner 29 can be characterized using a reference impedance for each port. This reference impedance corresponds to the impedance that must be connected to a given port to prevent reflection at the interface between this port and this impedance. Typically, the reference impedance is the same for each port.

Impedance matching networks 11, 25, 26, 27, 28 provide an impedance matching between the various ports of splitter 23 or combiner 29 to which they are connected at one end and the components to which they are connected on the other end. Each impedance matching network 11, 25, 26, 27, 28 can for example be embodied using one or more quarter wavelength transmission lines or lumped equivalents thereof.

Impedance matching network 25 provides an impedance match between the reference impedance at first output port p4 of hybrid coupler 23 and an input impedance of first amplifier 21, impedance matching network 26 provides an impedance match between the reference impedance at second output port p3 of hybrid coupler 23 and an input impedance of second amplifier 22, impedance matching network 27 provides an impedance match between the reference impedance at first input port p1 of hybrid coupler 29 and a target output impedance for first amplifier 21, impedance matching network 28 provides an impedance match between the reference impedance at second input port p2 of hybrid coupler 29 and a target output impedance for second amplifier 22, and impedance matching network 11 provides an impedance match between the reference impedance at isolated port p3 of hybrid coupler 29 and a target output impedance for main amplifier 10. The various target impedances correspond to the impedance that should be presented to an amplifier 11, 21, 22 such that it outputs a predefined output power. As an example, the target impedance for main amplifier 10 could equal 2×Ropt, and the target impedance for first amplifier 21 and second amplifier 22 could equal Ropt, wherein Ropt corresponds to the impedance that should be presented to an amplifier among amplifiers 10, 21, 22 such that it is capable of outputting saturated output power. These target impedances will be different when the maximum saturated power ratio for amplifiers 10, 21, 22 deviates from 1:1:1.

The amplified first and second parts of the second signal, and the amplified first signal, should be added in-phase by combiner 29. However, the total phase delay encountered for the various signals may differ. To account for the various phase delays, phase offset unit 40 should impart a phase delay to the second signal.

In FIG. 2, phase offset unit 40 is arranged in between main splitter 30 and splitter 23 of balanced amplifier 20. However, the phase offset unit could also comprise a first part arranged in between splitter 23 and first amplifier 21, and a second part arranged in between splitter 23 and second amplifier 22. Typically, the phase offset imparted by these parts would be substantially identical and equal to the phase delay imparted by phase offset unit 40 in FIG. 2.

It should be noted that the phase delay to be imparted by phase offset unit 40 not only depends on frequency but also on the power of the RF input signal. A trade off has therefore to be made to obtain a desired performance of PD-LMBA 1 over power and frequency. Hereinafter, the frequency dependent phase delay to be imparted by phase offset unit 40 will be referred to as desired phase delay behavior. An example thereof for a generic PD-LMBA is shown in FIG. 1. As described before, the desired phase delay behavior displays a stronger dependency on frequency than the phase delay that can be realized using a transmission line segment.

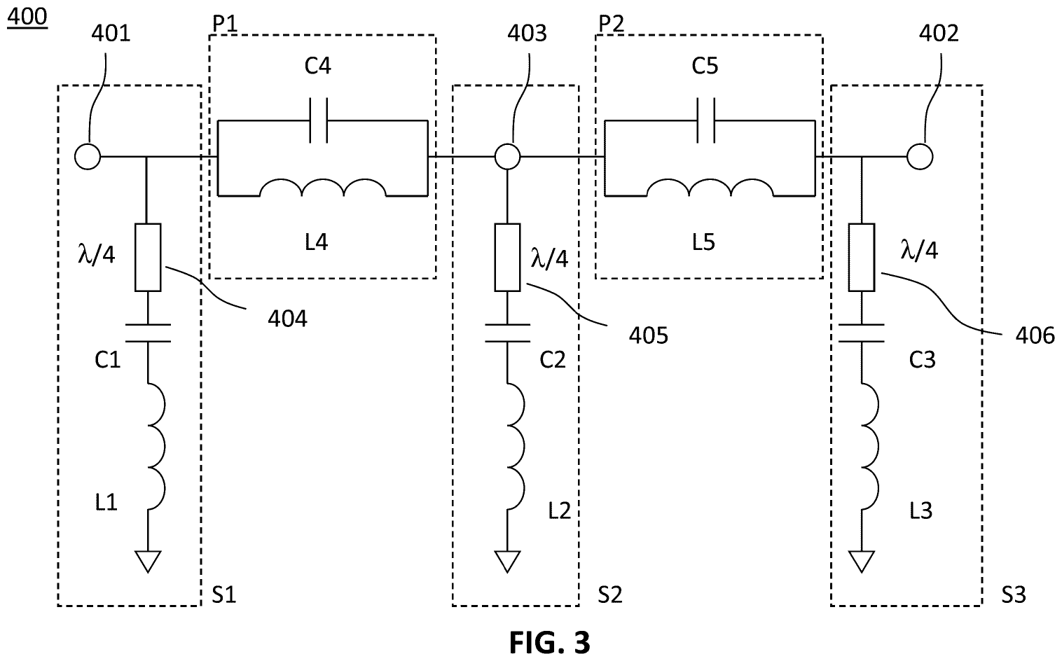

FIG. 3 illustrates an embodiment of a phase offset unit 400 with which the desired phase offset behavior can be obtained to a larger extent than with a transmission line segment.

Phase offset unit 400 comprises a three shunt series circuits S1, S2, S3 that are each connected to ground. Phase offset unit 400 further comprises two parallel resonance circuits P1, P2.

Each series circuit S1, S2, S3 comprises an impedance inverter in the form of a quarter wavelength transmission line 404, 405, 406 connected in series with a capacitor to ground. The transmission line is realized on a printed circuit board and the capacitor is an SMD mounted on the printed circuit board. Here, each SMD capacitor is modelled by a capacitor C1, C2, C3. Furthermore, an inductance associated with the connection to ground, for example the inductance of a through via in the printed circuit board, is modelled using inductors L1, L2, L3.

Main amplifier 10, first amplifier 21, and second amplifier 21 may correspond to packaged devices or semiconductor dies arranged on the printed circuit board. Splitters 23, 30 and combiner 29 can be embodied using SMD couplers arranged on the printed circuit board. Impedance matching networks 25, 26, 27, 28, 11 can be realized using transmission line segments on the printed circuit board and termination resistors 24, 31 can be realized using SMD resistors arranged on the printed circuit board. As an example, main amplifier 10, first amplifier 21, and/or second amplifier 22, can be realized using a Gallium Nitride based field-effect transistor or a Silicon based laterally diffused metal-oxide-semiconductor, LDMOS, transistor.

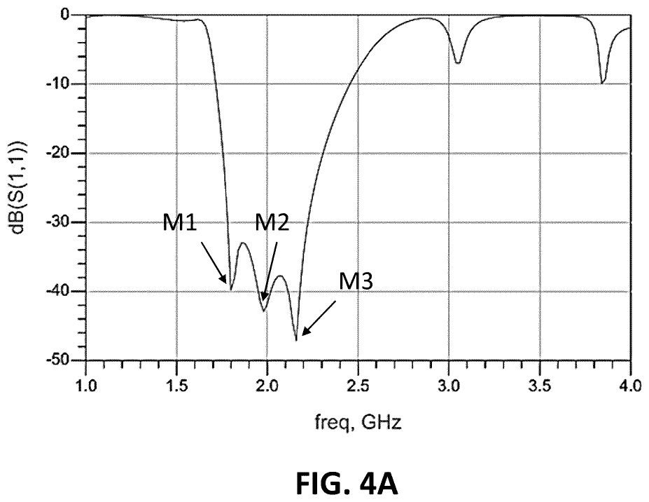

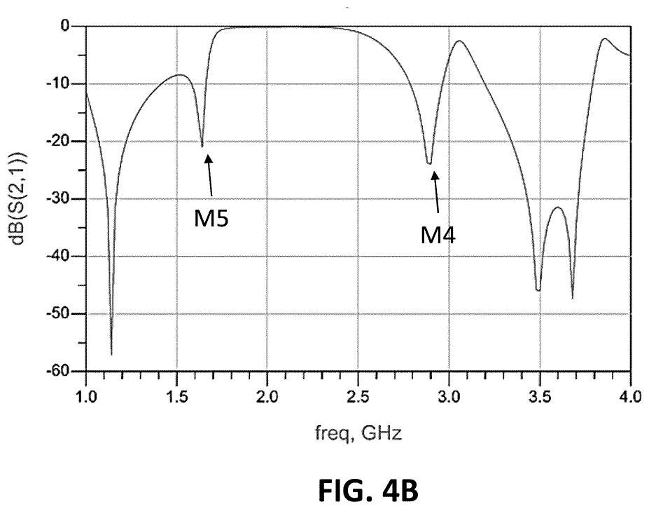

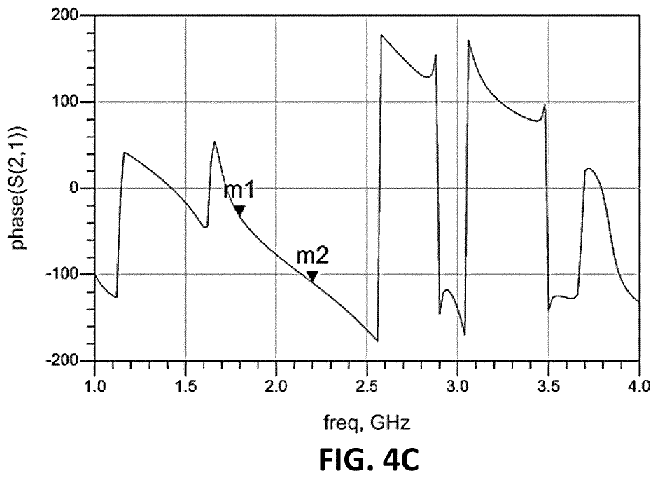

For each section, the quarter wavelength transmission lines convert the RF short generated by capacitors C1, C2, C3 to RF opens at respective first frequencies that lie inside or close to the frequency band that PD-LMBA 1 is configured to operate in. FIG. 4A illustrates the S11 parameter measured at input 401. As shown, S11 displays three minima M1, M2, M3 that can be associated with shunt series circuits S1, S2, S3, respectively. It is noted that if the inductance associated with the connection to ground of the SMD capacitor is insufficient together with the capacitance of the SMD capacitor to cause a resonance within the frequency band, it is possible to extend the length of the transmission line beyond that of a quarter wavelength. The extra inductance will lower the frequency of the series resonance.

Because the RF short is transformed into an RF open within the frequency band, shunt series circuits S1, S2, S3 have little impact on the overall impedance transformation of phase offset unit 400.

Parallel resonance circuits P1, P2 each comprises a transmission line segment of which the input and output are connected using a SMD capacitor. The SMD capacitor has a given inductance causing a series resonance at relatively high frequencies. For frequencies closer to the operating frequency band, the parallel connection of the SMD capacitor and the transmission line segment will introduce a parallel resonance that is configured to lie outside of the operating frequency band. At this parallel resonance, there will be little to no signal transfer between input 401 and output 402 of phase offset unit 400. These resonance frequencies can be identified in FIG. 4B that displays the magnitude of the S21 parameter for phase offset unit 400 and in FIG. 4C that displays the corresponding phase of S21. More in particular, minima M4 and M5 can be identified in S21 that are associated with parallel resonance circuits P1, P2.

The Applicant has found that the combination of at least one parallel resonance circuit P1, P2, and at least one shunt series circuit S1, S2, S3 allows a suitable phase delay to be imparted to the second signal while at the same guaranteeing impedance matching between second output port p3 of splitter 30 and input port p1 of splitter 23. This particularly holds if phase offset unit 400 comprises a series connection of one or more sections that each comprise an input, an output, a shunt series network connected to the input, and a parallel resonance circuit arranged in between the input and output, wherein for each pair of adjacent sections, the input of one section is connected to the output of the other section. The input of a first section among the one or more sections forms the input of the phase offset unit, and the output of the last section among the one or more sections forms the output of the phase offset unit. In this case, the output of the last section is connected to a shunt series circuit. For example, in FIG. 3, circuits S1 and P1 form a first section, and circuits S2 and P2 a second section. Output 402 is connected to shunt series circuit S3.

To obtain broadband behavior, it is important that the impedance ratio between the output impedance presented at the output of main amplifier 10 and the reference impedance of hybrid coupler 29 is not too large. The same holds for the impedance ratio between the output impedance presented at the output of first and second amplifiers 21, 22 and the reference impedance of hybrid coupler 29. Especially for high power applications, the impedances presented at the outputs of amplifiers 10, 21, 22 is relatively low. To address the need for improving the bandwidth of the PD-LMBA while still offering a compact solution, the present disclosure proposes to stack discrete couplers. In some examples, these couplers may be symmetric such that the reference impedance at all ports of a given coupler is identical. However, this reference impedance may differ among the stacked couplers.

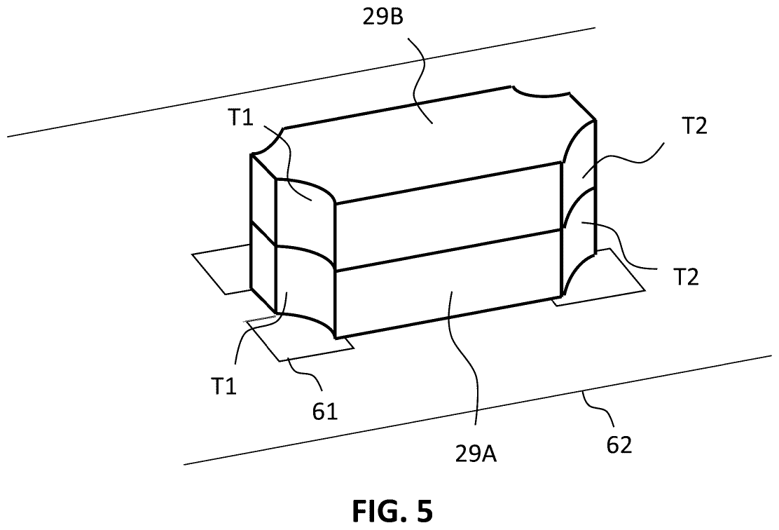

FIG. 5 illustrates an example of stacked discrete couplers 29A, 29B that can be used as hybrid coupler 29 in the PD-LMBA of FIG. 2. In this figure it is shown that the terminal areas T1, T2 of ports p1 and p2 of couplers 29A, 29B are aligned. Terminal areas T1 and T2 are made from conductive material, such as one or more metals. A fixed and electrically conductive connection between couplers 29A and 29B can be realized using a conductive connection agent that simultaneously contacts areas T1, T2. An example of such a conductive connection agent is formed by solder or a conductive glue.

To arrange the stack of discrete couplers, it is possible to first mount a first coupler 29A onto pads 61 on a printed circuit board 62. It is noted that printed circuit board 62 is the same printed circuit board as described above, i.e. the printed circuit board on which amplifiers 10, 21, 22 are mounted.

To mount coupler 29A, its terminal areas, such as areas T1 and T2, are connected to corresponding pads 61 using solder. As a next step, a coupler 29B can be placed on top of coupler 29A in the manner shown in FIG. 5. After this alignment, the corresponding terminal areas can be connected using solder or the like.

The Applicant has found that the combination of stacked couplers behaves as a coupler having a lower reference impedance for each port. For example, if the stack comprises two couplers of which the reference impedances are Z1 and Z2, the combination of these two couplers will have a reference impedance for each port that equals Z1Z2/(Z1+Z2).

In the above, the present invention has been described using detailed embodiments thereof. However, the present invention is not limited to these embodiments. Rather, various modifications are possible without departing from the scope of the present invention, which is defined by the appended claims and their equivalents.

What is claimed is:

1. A pseudo-Doherty load modulated balanced amplifier, PD-LMBA, configured to operate in a given frequency band and comprising:
a main splitter for splitting an input RF signal into a first signal and a second signal;
a main amplifier for amplifying the first signal;
a balanced amplifier for amplifying the second signal, said balanced amplifier comprising:
a splitter for splitting the second signal into a first part and a second part of the second signal;
a first amplifier and a second amplifier for amplifying the first part of the second signal and the second part of the second signal, respectively; and
a combiner,
wherein the combiner is configured for combining the amplified first signal, the amplified first part of the second signal, and the amplified second part of the second signal into an output RF signal; and
a phase offset unit arranged upstream from the first amplifier and the second amplifier and downstream of the main splitter, wherein the phase offset unit comprises:
at least one shunt series circuit connected to ground, each shunt series circuit comprising an impedance inverter and a termination circuit arranged in between the impedance inverter and ground, wherein the termination circuit is configured to present an RF short to the impedance inverter at a first frequency that lies inside or close to the frequency band, and wherein the impedance inverter is configured to transform the RF short to an RF open at the first frequency; and
at least one parallel resonance circuit arranged in between an input and an output of the phase offset unit, wherein an impedance of the at least one parallel resonance circuit corresponds to an RF open at a second frequency that lies outside the frequency band,
wherein the first frequency lies closer to a center frequency of the frequency band than the second frequency does.

2. The PD-LMBA according to claim 1, wherein the impedance converter of at least one shunt series circuit comprises a quarter wavelength transmission line or equivalent thereof.

3. The PD-LMBA according to claim 1,
wherein said at least one shunt series circuit comprises a first shunt series circuit connected between the input of the phase offset unit and ground and a second shunt series circuit connected between the output of the phase offset unit and ground,
wherein said at least one parallel resonance circuit comprises a first parallel resonance circuit connected between the input and the output of the phase offset unit, and
wherein the first frequency of the first shunt series circuit is different from the first frequency of the second shunt series circuit.

4. The PD-LMBA according to claim 3,
wherein said at least one parallel resonance circuit comprises a second parallel resonance circuit connected between the first parallel resonance circuit and the output of the phase offset unit,
wherein the second parallel resonance circuit and the first parallel resonance circuit are connected at an intermediate node,
wherein said at least one shunt series circuit comprises a third shunt series circuit connected between the intermediate node and ground,
wherein the first frequency of the third shunt series circuit is different from the first frequency of the first shunt series circuit and different from the first frequency of the second shunt series circuit, and
wherein the second frequency of the first parallel resonance circuit is different from the second frequency of the second parallel resonance circuit.

5. The PD-LMBA according to claim 4, wherein the first frequencies of the first shunt series circuit, the second shunt series circuit, and the third shunt series circuit are situated, inside the frequency domain, in between the second frequencies of the first parallel resonance circuit and the second parallel resonance circuit.

6. The PD-LMBA according to claim 1, further comprising a printed circuit board or a laminate substrate, wherein the main amplifier and the balanced amplifier are comprised by one or more semiconductor dies on the printed circuit board or the laminate substrate, in a packaged form or as a discrete semiconductor die, and wherein the impedance inverter of at least one of said at least one shunt series circuits is embodied as a transmission line on the printed circuit board or the laminate substrate.

7. The PD-LMBA according to claim 6, wherein the termination circuit of at least one of said at least one shunt series circuit comprises a surface mounted device, SMD, capacitor that is connected to ground or a SMD capacitor that is connected to ground through a via in the printed circuit board or the laminate substrate.

8. The PD-LMBA according to claim 6, wherein at least one of said at least one parallel resonance circuit comprises a transmission line on the printed circuit board or the laminate substrate arranged in parallel to a surface mounted device, SMD, capacitor.

9. The PD-LMBA according to claim 1, wherein the combiner of the balanced amplifier comprises a first coupler having: a first input port; a second input port; an output port; and an isolated port, wherein the first input port is connected to an output of the first amplifier, the second input port is connected to an output of the second amplifier, and the isolated port is connected to an output of the main amplifier, wherein the output port is configured to be connected to a load, and wherein each of the first input port, the second input port, the output port, and the isolated port have a respective reference impedance Z_{ref}.

10. The PD-LMBA according to claim 9, wherein the reference impedance for each of the first input port, the second input port, the output port, and the isolated port is identical.

11. The PD-LMBA according to claim 10, wherein the first coupler comprises n stacked discrete couplers, wherein each discrete coupler has a respective port impedance Zᵢ that is identical for all ports and that is higher than Z_{ref}, wherein n is an integer number greater than 1, wherein i indicates the i-th discrete coupler with i an integer number ranging from 1 to n, and wherein:
$$\frac{1}{{Z}_{ref}} = {\sum }_{i = 1}^{n} \frac{1}{{Z}_{i}}$$

12. The PD-LMBA according to claim 11, wherein Zᵢ=Z_{coupler} for all i.

13. The PD-LMBA according to claim 11, wherein Z_{ref} is between 5 Ohm and 30 Ohm, n equals 2, 3, or 4, or Z_{coupler} equals 25 Ohm, 50 Ohm, or 75 Ohm.

14. The PD-LMBA according to claim 10, wherein corresponding ports of adjacent discrete couplers in the stack of discrete couplers are electrically connected or are electrically connected using solder.

15. The PD-LMBA according to claim 9, further comprising:
a first impedance matching network arranged in between the output of the first amplifier and the first coupler and being configured for providing an upward impedance transformation, in a direction from the first amplifier to the first coupler, to the reference impedance Z_{ref} associated with the first input port of the first coupler;
a second impedance matching network arranged in between the output of the second amplifier and the first coupler and being configured for providing an upward impedance transformation, in a direction from the second amplifier to the first coupler, to the reference impedance Z_{ref} associated with the second input port of the first coupler;
a third impedance matching network arranged in between the output of the main amplifier and the first coupler and being configured for providing an upward impedance transformation, in a direction from the main amplifier to the first coupler, to the reference impedance Z_{ref} associated with the isolated input port of the first coupler.

16. The PD-LMBA according to claim 1, further comprising a fourth impedance matching network arranged in between the output port of the first coupler and the output of the PD-LMBA, wherein the fourth impedance matching network is configured for providing an upward impedance transformation between Z_{ref} and an impedance of a load to be connected to the output of the PD-LMBA.

17. The PD-LMBA according to claim 1,
wherein the splitter of the balanced amplifier comprises a second coupler,
wherein the second coupler comprises:
an input port connected to the main splitter;
a first output port connected to an input of the first amplifier;
a second output port connected to an input of the second amplifier; and
an isolated port,
wherein the phase offset unit is connected between the main splitter and the input port of the second coupler, and
wherein the PD-LMBA further comprises:
a fourth impedance matching network arranged between the first output port of the second coupler and the input of the first amplifier; and
a fifth impedance matching network arranged between the second output port of the second coupler and the input of the second amplifier.

18. The PD-LMBA according to claim 1,
wherein the main splitter comprises a third coupler, and
wherein the third coupler comprises:
an input port connected to an input of the PD-LDMA;
a first output port connected to the input port of the second coupler or connected to the input port of the second coupler through the phase offset unit;
a second output port connected to an input of the main amplifier; and
an isolated port.

19. The PD-LMBA according claim 1, wherein the first coupler, the second coupler, or the third coupler comprises a hybrid coupler, a Lange coupler, a directional coupler, a coupled-line coupler, a strip line coupler, a branch line coupler, a wave guide couplers, or a coax coupler,
wherein each of the first amplifier, the second amplifier, and the main amplifier comprises a power transistor, a Silicon based laterally diffused metal oxide semiconductor field-effect transistor, or a Gallium Nitride based field-effect transistor, and
wherein:
a center frequency corresponding to the frequency band is between 0.5 GHz and 8 GHz,
a bandwidth of the frequency band relative to the center frequency is between 10% and 40%; or
the PD-LMBA is configured to output a maximum output power between 10 mW and 500 W.

20. A mobile telecommunications base station comprising the PD-LMBA according to claim 1.
